(19) United States
(12) Patent Application Publication
(10) Pub. No.: US 2026/0136913 A1
(43) Pub. Date: May 14, 2026

(54) SEMICONDUCTOR DEVICE

(71) Applicant: Samsung Electronics Co., Ltd., Suwon-si (KR)

(72) Inventors: Seung CHOI, Suwon-si (KR); Jin Woo JEONG, Suwon-si (KR); Byung-Sung KIM, Suwon-si (KR); Sung Ho PARK, Suwon-si (KR)

(21) Appl. No.: 19/245,270

(22) Filed: Jun. 21, 2025

(30) Foreign Application Priority Data
Nov. 13, 2024 (KR) 10-2024-0160880

(51) Int. Cl. H01L 23/528; H01L 23/522; H10D 30/00; H10D 62/10; H10D 62/13; H10D 64/23; H10D 84/83

(52) U.S. Cl. CPC H10W 20/43; H10D 30/502; H10D 62/121; H10D 62/151; H10D 64/256; H10D 84/83125; H10D 84/832; H10W 20/42; H10W 20/427; H10W 20/435

(57) ABSTRACT

A semiconductor device includes a substrate, first and second active patterns, first and second gate structures intersecting the first active pattern, third and fourth gate structures intersecting the second active pattern, first level wiring patterns disposed at a first level on the substrate and including first to fourth lower wiring patterns connected to the first to fourth gates, respectively, and a fifth lower wiring pattern, and second level wiring patterns disposed at a second level higher than the first level substrate and including a first upper wiring pattern and a second upper wiring pattern. The first upper wiring pattern connects the second lower wiring pattern to the third lower wiring pattern. A second upper wiring pattern connects the fourth lower wiring pattern to the fifth lower wiring pattern. The first lower wiring pattern is electrically connected to the fifth lower wiring pattern.

This application claims priority under 35 U.S.C. § 119 to Korean Patent Application No. 10-2024-0160880, filed on Nov. 13, 2024 in the Korean Intellectual Property Office, the disclosure of which is incorporated by reference herein in its entirety.

### BACKGROUND

### 1. Technical Field

The present invention relates to a semiconductor device. More specifically, the present invention relates to a semiconductor device including a cross-gate connection structure.

### 2. Description of the Related Art

Due to characteristics such as a miniaturization, a multi-functionality, and/or a low fabricating cost, semiconductor devices are in the spotlight as important elements in the electronics industry. The semiconductor devices may be classified into a semiconductor memory device that stores logical data, a semiconductor logic device that performs a computation process on the logical data, and a hybrid semiconductor device that includes memory elements and logic elements.

As the electronics industry develops to a high level, the demands for the characteristics of the semiconductor devices are gradually increasing. For example, the demands for a high reliability, a high speed, and/or a multi-functionality of the semiconductor devices are gradually increasing. In order to satisfy such required characteristics, the structures inside the semiconductor device are gradually becoming complex and highly integrated. For example, in the design of the semiconductor device, a so-called cross-gate connection structure in which two pairs of gates are connected to intersect may be used.

### SUMMARY

Aspects of the present inventive concept provide a semiconductor device having improved performance.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

According to example embodiments, a semiconductor device includes a substrate, a first active pattern which extends in a first direction on the substrate, a second active pattern which is spaced apart from the first active pattern in a second direction intersecting the first direction, and extends in the first direction on the substrate, a first gate structure which intersects the first active pattern, a second gate structure which is spaced apart from the first gate structure in the first direction, and intersects the first active pattern, a third gate structure which is spaced apart from the first gate structure in the second direction, and intersects the second active pattern, a fourth gate structure which is spaced apart from the second gate structure in the second direction, and intersects the second active pattern, first level wiring patterns which are disposed at a first level on the basis of an upper face of the substrate, and include first to fifth lower wiring patterns each extending in the first direction, and second level wiring patterns which are disposed at a second level higher than the first level on the basis of the upper face of the substrate, and include a first upper wiring pattern and a second upper wiring pattern. The first to fourth lower wiring patterns are connected to the first to fourth gate structures, respectively. The fifth lower wiring pattern is interposed between the second lower wiring pattern and the fourth lower wiring pattern. The first upper wiring pattern includes a first extension extending in the first direction and connected to the second lower wiring pattern, and a second extension extending in the second direction from the first extension and connected to the third lower wiring pattern. The second upper wiring pattern extends in the second direction and connects the fourth lower wiring pattern and the fifth lower wiring pattern. The fifth lower wiring pattern is electrically connected to the first lower wiring pattern.

According to example embodiments, a semiconductor device includes a substrate, a first active pattern which extends in a first direction on the substrate, a second active pattern which is spaced apart from the first active pattern in a second direction intersecting the first direction, and extends in the first direction on the substrate, a first gate structure which intersects the first active pattern, a second gate structure which is spaced apart from the first gate structure in the first direction, and intersects the first active pattern, a third gate structure which is spaced apart from the first gate structure in the second direction, and intersects the second active pattern, a fourth gate structure which is spaced apart from the second gate structure in the second direction, and intersects the second active pattern, first level wiring patterns which are disposed at a first level on the basis of an upper face of the substrate, the first level wiring patterns including a first power supply wiring and a second power supply wiring each extending in the first direction and spaced apart from each other in the second direction, second level wiring patterns which are disposed at a second level higher than the first level on the basis of the upper face of the substrate, the second level wiring patterns including a first upper wiring pattern and a second upper wiring pattern, a connecting pattern, and first to fourth routing tracks which are arranged sequentially along the second direction and each extend in the first direction are defined between the first power supply wiring and the second power supply wiring. The first level wiring patterns include a first lower wiring pattern connected to the first gate structure in the first routing track, a second lower wiring pattern connected to the second gate structure in the first routing track, a third lower wiring pattern connected to the third gate structure in the fourth routing track, a fourth lower wiring pattern connected to the fourth gate structure in the fourth routing track, and a fifth lower wiring pattern in the third routing track. The first upper wiring pattern includes a first extension extending in the first direction and connected to the second lower wiring pattern, and a second extension extending in the second direction from the first extension and connected to the third lower wiring pattern. The second upper wiring pattern extends in the second direction and connects the fourth lower wiring pattern and the fifth lower wiring pattern. The connecting pattern extends in the second direction and connects the first lower wiring pattern and the fifth lower wiring pattern.

According to example embodiments, a semiconductor device includes a substrate, a first active pattern which extends in a first direction on the substrate, a second active pattern which is spaced apart from the first active pattern in a second direction intersecting the first direction, and extends in the first direction on the substrate, a first gate structure which intersects the first active pattern, a second gate structure which is spaced apart from the first gate structure in the first direction, and intersects the first active pattern, a third gate structure which is spaced apart from the first gate structure in the second direction, and intersects the second active pattern, a fourth gate structure which is spaced apart from the second gate structure in the second direction, and intersects the second active pattern, a fifth gate structure which is spaced apart from the first gate structure and the third gate structure in the first direction, and intersects the first active pattern and the second active pattern, first level wiring patterns which are disposed at a first level on the basis of an upper face of the substrate, and include first to fifth lower wiring patterns each extending in the first direction, second level wiring patterns which are disposed at a second level higher than the first level on the basis of the upper face of the substrate, and include a first upper wiring pattern and a second upper wiring pattern, and a connecting pattern which is connected to a first source/drain region of the first active pattern on a side face of the fifth gate structure. The first to fourth lower wiring patterns are connected to the first to fourth gate structures, respectively. The fifth lower wiring pattern is interposed between the second lower wiring pattern and the fourth lower wiring pattern. The first upper wiring pattern includes a first extension extending in the first direction and connected to the second lower wiring pattern, and a second extension extending in the second direction from the first extension and connected to the third lower wiring pattern. The second upper wiring pattern extends in the second direction and connects the fourth lower wiring pattern and the fifth lower wiring pattern. The connecting pattern extends in the second direction, and connects the first lower wiring pattern and the fifth lower wiring pattern.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is an exemplary layout diagram for explaining a semiconductor device according to some embodiments;

FIG. 2 is a cross-sectional view taken along A-A of FIG. 1 according to some embodiments;

FIG. 3 is a cross-sectional view taken along B-B of FIG. 1 according to some embodiments;

FIG. 4 is a cross-sectional view taken along C-C of FIG. 1 according to some embodiments;

FIG. 5 is a cross-sectional view taken along D-D of FIG. 1 according to some embodiments;

FIG. 6 is a cross-sectional view taken along E-E of FIG. 1 according to some embodiments;

FIG. 7 is a partial layout diagram for explaining a cross-gate connection structure of the semiconductor device of FIG. 1 according to some embodiments;

FIG. 8 is an exemplary layout diagram for explaining a semiconductor device according to some embodiments.

FIG. 9 is a cross-sectional view taken along F-F of FIG. 8 according to some embodiments;

FIG. 10 is a partial layout diagram for explaining the cross-gate connection structure of the semiconductor device of FIG. 8 according to some embodiments;

FIG. 11 is an exemplary layout diagram for explaining a semiconductor device according to some embodiments.

FIG. 12 is a partial layout diagram for explaining a cross-gate connection structure of the semiconductor device of FIG. 11 according to some embodiments;

FIG. 13 is an exemplary layout diagram for explaining a semiconductor device according to some embodiments.

FIG. 14 is a partial layout diagram for explaining the cross-gate connection structure of the semiconductor device of FIG. 13 according to some embodiments;

FIGS. 15 and 16 are exemplary layout diagrams for explaining a semiconductor device according to some embodiments according to some embodiments; and

FIGS. 17 to 22 are various exemplary layout diagrams for explaining a semiconductor device according to some embodiments.

### DETAILED DESCRIPTION

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

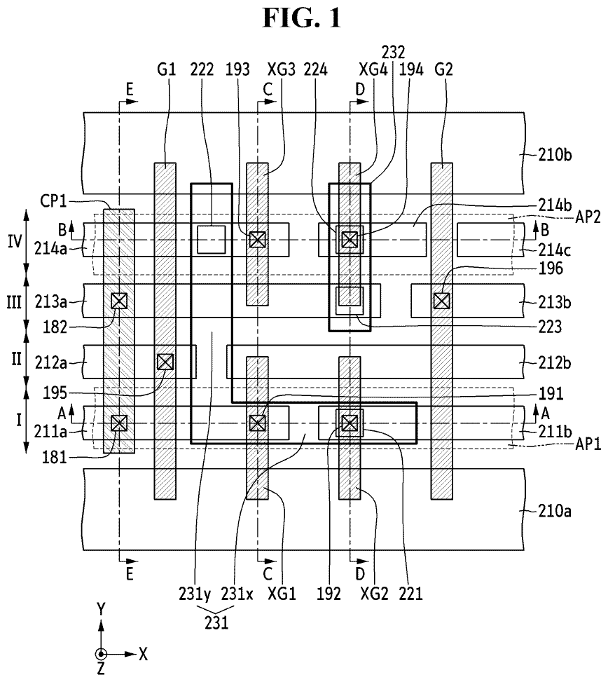

Hereinafter, a semiconductor device according to exemplary embodiments will be described referring to FIGS. 1 to 22.

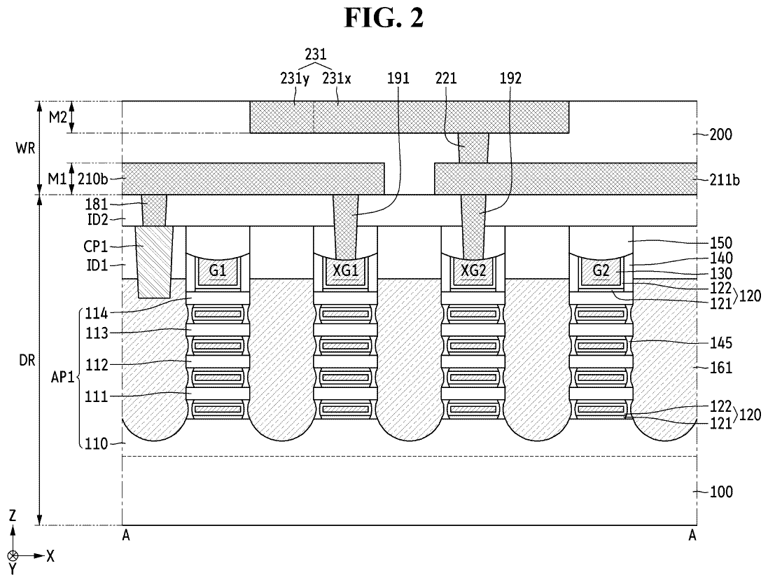

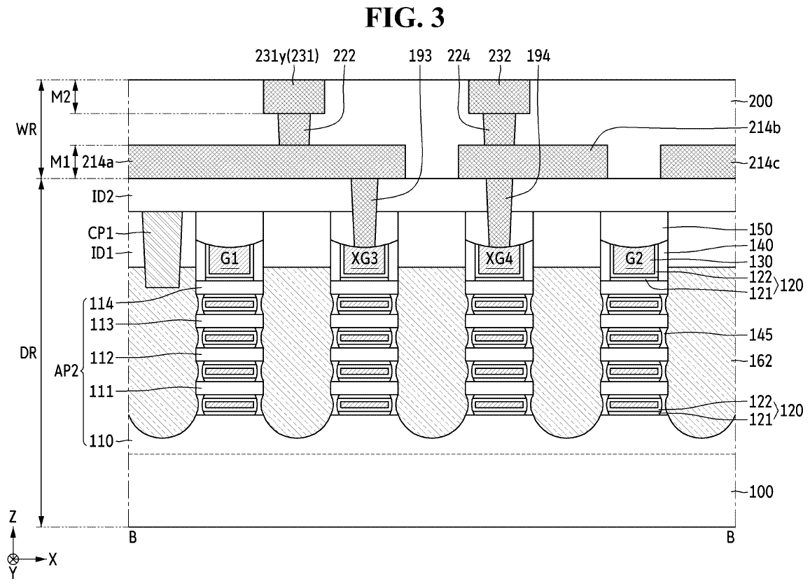

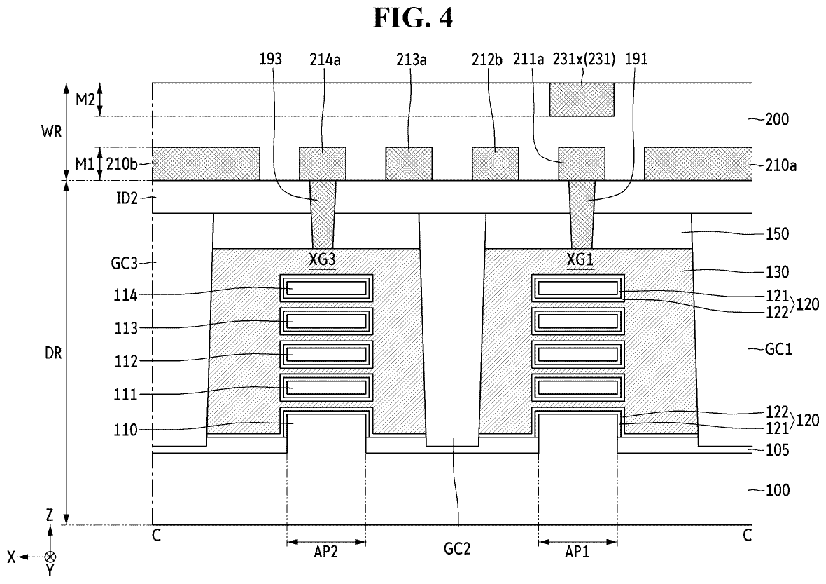

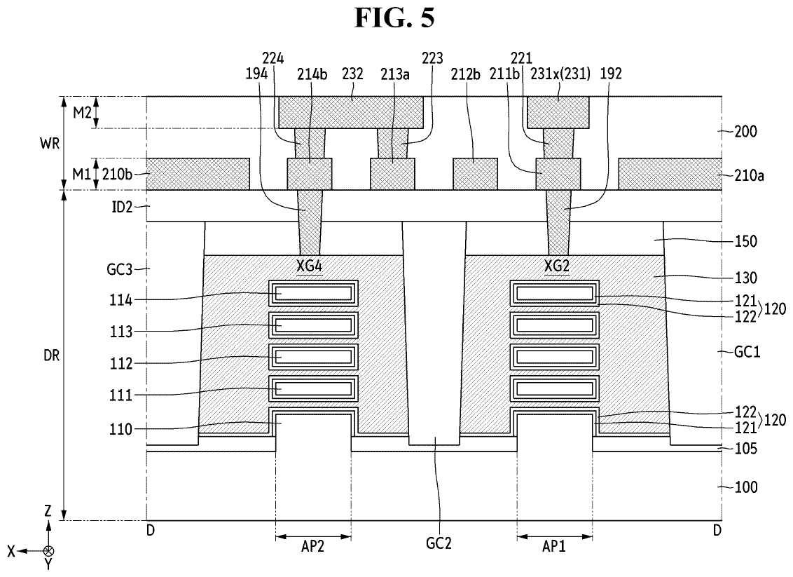

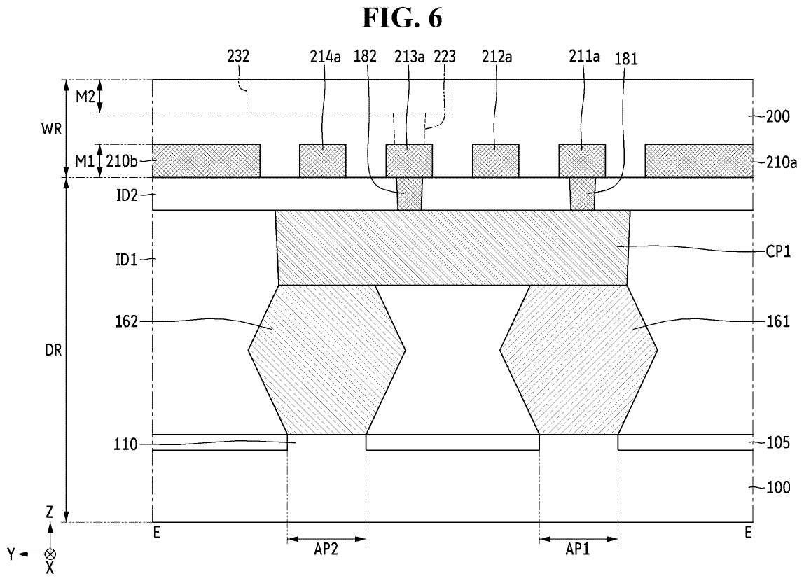

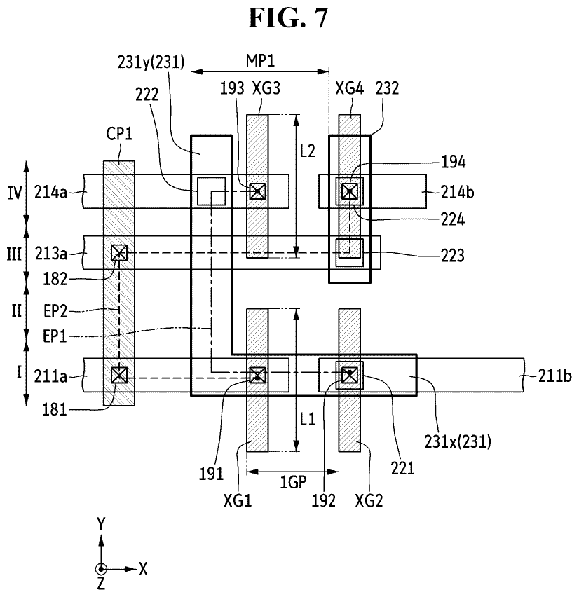

FIG. 1 is an exemplary layout diagram for explaining a semiconductor device according to some embodiments. FIG. 2 is a cross-sectional view taken along A-A of FIG. 1 according to some embodiments. FIG. 3 is a cross-sectional view taken along B-B of FIG. 1 according to some embodiments. FIG. 4 is a cross-sectional view taken along C-C of FIG. 1 according to some embodiments. FIG. 5 is a cross-sectional view taken along D-D of FIG. 1 according to some embodiments. FIG. 6 is a cross-sectional view taken along E-E of FIG. 1 according to some embodiments. FIG. 7 is a partial layout diagram for explaining a cross-gate connection structure of the semiconductor device of FIG. 1 according to some embodiments.

Referring to FIGS. 1 to 7, the semiconductor device according to some embodiments includes an element region DR and a wiring region WR.

The element region DR may include a substrate 100, a field insulating film 105, first and second active patterns AP1 and AP2, first to sixth gate structures XG1 to XG4, G1 and G2, first to third cut patterns GC1 to GC3, first and second source/drain regions 161 and 162, a first interlayer insulating film ID1, and a second interlayer insulating film ID2.

The substrate 100 may be bulk silicon or silicon-on-insulator (SOI). In contrast, the substrate 100 may be a silicon substrate, or may include other materials, for example, silicon germanium, silicon germanium on insulator (SGOI), indium antimonide, lead telluride, indium arsenide, indium phosphide, gallium arsenide or gallium antimonide. Alternatively, the substrate 100 may be a base substrate on which an epitaxial layer is formed.

The first and second active patterns AP1 and AP2 may be formed on the substrate 100. The first and second active patterns AP1 and AP2 may each extend long in a first direction X parallel to an upper face of the substrate 100. The first and second active patterns AP1 and AP2 may be spaced apart from each other in a second direction Y that is parallel to the upper face of the substrate 100 and intersects the first direction X.

The first and second active patterns AP1 and AP2 may each include silicon (Si) or germanium (Ge) which is an elemental semiconductor material. Alternatively, the first and second active patterns AP1 and AP2 may each include a compound semiconductor, for example, a group IV-IV compound semiconductor or a group III-V compound semiconductor. The group IV-IV compound semiconductor may be, for example, a binary compound or a ternary compound including at least two or more of carbon (C), silicon (Si), germanium (Ge), and tin (Sn), or a compound formed by doping these elements with a group IV element. The group III-V compound semiconductor may be, for example, one of binary compounds, ternary compounds or quaternary compounds formed by combining at least one of aluminum (Al), gallium (Ga) and indium (In), which are group III elements, with one of phosphorus (P), arsenic (As) and antimonium (Sb), which are group V elements.

In some embodiments, the first and second active patterns AP1 and AP2 may be provided as channel regions of different conductivity types from each other. In the following description, an example in which the first active pattern AP1 is a channel region of an N-type Field-Effect Transistor (NFET), and the second active pattern AP2 is a channel region of a P-type Field-Effect Transistor (PFET) will be provided. However, this is merely an example, and it goes without saying that the first active pattern AP1 may be the channel region of the PFET, and the second active pattern AP2 may be the channel region of the NFET.

In some embodiments, each of the first and second active patterns AP1 and AP2 may include a plurality of bridge patterns 111 to 114. The plurality of bridge patterns 111 to 114 may be spaced apart from each other and sequentially stacked in a third direction Z that intersects the upper face of the substrate 100. The bridge patterns 111 to 114 may be used as a channel region of a Multi-Bridge Channel Field-Effect Transistor (MBCFET) including a multi-bridge channel. The number of bridge patterns 111 to 114 included in each of the first and second active patterns AP1 and AP2 is merely an example, and is not limited to that shown.

In some embodiments, each of the first and second active patterns AP1 and AP2 may further include a fin pattern 110 between the substrate 100 and the bridge patterns 111 to 114. The fin pattern 110 may protrude from the upper face of the substrate 100 and extend long in the first direction X. The bridge patterns 111 to 114 may be spaced apart from the fin pattern 110 in the third direction Z. The fin pattern 110 may be formed by etching a part of the substrate 100, or may be an epitaxial layer grown from the substrate 100.

The field insulating film 105 may be formed on the substrate 100. The field insulating film 105 may cover at least a part of the side face of the fin pattern 110. The field insulating film 105 may include, for example, but not limited to, at least one of silicon oxide, silicon nitride, silicon oxynitride, and combinations thereof.

The first to sixth gate structures XG1 to XG4, G1, and G2 may be formed on the first and second active patterns AP1 and AP2 and the field insulating film 105. The first to sixth gate structures XG1 to XG4, G1, and G2 may each extend long in the second direction Y. Each of the first to sixth gate structures XG1 to XG4, G1, and G2 may intersect at least one of the first active pattern AP1 and the second active pattern AP2. For example, the bridge patterns 111 to 114 may extend in the first direction X and penetrate the first to sixth gate structures XG1 to XG4, G1, and G2.

The first gate structure XG1 may intersect the first active pattern AP1. The second gate structure XG2 may be spaced apart from the first gate structure XG1 in the first direction X. The second gate structure XG2 may intersect the first active pattern AP1. The third gate structure XG3 may be spaced apart from the first gate structure XG1 in the second direction Y. The third gate structure XG3 may intersect the second active pattern AP2. The fourth gate structure XG4 may be spaced apart from the second gate structure XG2 in the second direction Y. The fourth gate structure XG4 may intersect the second active pattern AP2.

In some embodiments, the first to fourth gate structures XG1 to XG4 may be arranged symmetrically in the second direction Y. For example, as shown in FIG. 7, a first length L1 of the first gate structure XG1 (or the second gate structure XG2) extending in the second direction Y may be equal to a second length L2 of the third gate structure XG3 (or the fourth gate structure XG4) extending in the second direction Y. In this specification, the term “same” means not only exactly the same thing but also includes a slight difference that may occur due to a process margin or the like.

The first to fourth gate structures XG1 to XG4 may be disposed between the fifth gate structure G1 and the sixth gate structure G2. The fifth gate structure G1 may be spaced apart from the first gate structure XG1 and the third gate structure XG3 in the first direction X. The fifth gate structure G1 may intersect the first active pattern AP1 and the second active pattern AP2. The sixth gate structure G2 may be spaced apart from the second gate structure XG2 and the fourth gate structure XG4 in the first direction X. The sixth gate structure G2 may intersect the first active pattern AP1 and the second active pattern AP2.

Each of the first to sixth gate structures XG1 to XG4, G1, and G2 may include a gate dielectric film 120, a gate electrode 130, a gate spacer 140, and a gate capping film 150.

The gate dielectric film 120 may be interposed between each of the first and second active patterns AP1 and AP2 and the gate electrode 130. The gate dielectric film 120 may be interposed between the field insulating film 105 and the gate electrode 130.

The gate dielectric film 120 may include a dielectric material, for example, at least one of silicon oxide, silicon oxynitride, silicon nitride or a high-k material having a higher dielectric constant than silicon oxide. For example, the high-k material may include, but not limited to, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), and combinations thereof.

In some embodiments, the gate dielectric film 120 may include an interfacial film 121 and a high dielectric film 122 that are sequentially stacked on the first and second active patterns AP1 and AP2.

The interfacial film 121 may surround the periphery of each of the bridge patterns 111 to 114. The interfacial film 121 may extend conformally along the periphery of each of the bridge patterns 111 to 114. The interfacial film 121 may extend along the surface of the fin pattern 110 exposed from the field insulating film 105. In some embodiments, the interfacial film 121 may include an oxide film formed by oxidation of the surfaces of each of the bridge patterns 111 to 114. As an example, when each of the bridge patterns 111 to 114 is a silicon (Si) pattern, the interfacial film 121 may include a silicon oxide film.

The high dielectric film 122 may surround the periphery of the interfacial film 121. In some embodiments, a part of the high dielectric film 122 may be interposed between the gate electrode 130 and the gate spacer 140. For example, the high dielectric film 122 may extend conformally along the periphery of the interfacial film 121 and the profile of the inner side face of the gate spacer 140. The high dielectric film 122 may further extend along the upper face of the field insulating film 105. The high dielectric film 122 may include a high dielectric constant material having a higher dielectric constant than silicon oxide.

The gate electrode 130 may extend long in the second direction Y to intersect at least one of the first active pattern AP1 or the second active pattern AP2. Each of the bridge patterns 111 to 114 may extend in the second direction Y and penetrate the gate electrode 130. The gate electrode 130 may include a conductive material, for example, but not limited to, at least one of TiN, WN, TaN, Ru, TiC, TaC, Ti, Ag, Al, TiAl, TiAlN, TiAlC, TaCN, TaSiN, Mn, Zr, W, Al, and combinations thereof. The gate electrode 130 may be formed by, but not limited to, a replacement process.

Although the gate electrode 130 is shown to be a single film, this is merely exemplary, and it is a matter of course that the gate electrode 130 may be a multi-layer film formed by stacking a plurality of conductive films. The gate electrode 130 may include, for example, a work function adjustment film for adjusting a work function, and a filling conductive film that fills a space formed by the work function adjustment film. The work function control film may include, for example, at least one of TiN, TaN, TiC, TaC, TiAlC, and combinations thereof. The filling conductive film may include, for example, W or Al. The gate spacer 140 may extend along the side face of the gate electrode 130. Each of the bridge patterns 111 to 114 may extend in the second direction Y and penetrate the gate spacer 140. The gate spacer 140 may include an insulating material, for example, but not limited to, at least one of silicon oxide, silicon nitride, silicon oxynitride, silicon oxycarbide, silicon boron nitride, silicon boron carbonitride, silicon oxycarbon nitride, and combinations thereof.

The gate capping film 150 may extend along the upper face of the gate electrode 130. The gate capping film 150 may include an insulating material, for example, but not limited to, at least one of silicon oxide, silicon nitride, silicon oxynitride, silicon oxycarbide, silicon boron nitride, silicon boron carbonitride, silicon oxycarbon nitride, and combinations thereof.

In some embodiments, each of the first to sixth gate structures XG1 to XG4, G1, and G2 may further include an inner spacer 145. The inner spacer 145 may be formed on the side face of the gate electrode 130 between the bridge patterns 111 to 114. The inner spacers 145 may be formed on the side faces of the gate electrode 130 between the fin pattern 110 and the bridge patterns 111 to 114. The inner spacer 145 may include an insulating material, for example, but not limited to, at least one of silicon oxide, silicon nitride, silicon oxynitride, silicon oxycarbide, silicon boron nitride, silicon boron carbonitride, silicon oxycarbon nitride, and combinations thereof.

The first to third cut patterns GC1 to GC3 may be formed on the field insulating film 105. The first to third cut patterns GC1 to GC3 may each extend long in the first direction X. The first to third cut patterns GC1 to GC3 may cut the first to sixth gate structures XG1 to XG4, G1, and G2.

For example, a second cut pattern GC2 may be disposed between the first active pattern AP1 and the second active pattern AP2, the first active pattern AP1 may be disposed between the first cut pattern GC1 and the second cut pattern GC2, and the second active pattern AP2 may be disposed between the second cut pattern GC2 and the third cut pattern GC3. The first cut pattern GC1 may cut the first, second, fifth and sixth gate structures XG1, XG2, G1 and G2. The second cut pattern GC2 may separate the first gate structure XG1 from the third gate structure XG3, and may separate the second gate structure XG2 from the fourth gate structure XG4. The third cut pattern GC3 may cut the third, fourth, fifth and sixth gate structures XG3, XG4, G1 and G2.

In some embodiments, the fifth and sixth gate structures G1 and G2 may not be cut by the second cut pattern GC2. For example, the second cut pattern GC2 may be interposed between the fifth gate structure G1 and the sixth gate structure G2 in the first direction X.

Each of the first to third cut patterns GC1 to GC3 may include an insulating material, for example, but not limited to, at least one of silicon oxide, silicon nitride, silicon oxynitride, silicon oxycarbide, silicon boron nitride, silicon boron carbonitride, silicon oxycarbon nitride, and combinations thereof.

In some embodiments, a distance (e.g., L1 of FIG. 7) by which the first cut pattern GC1 and the second cut pattern GC2 are spaced apart from each other in the second direction Y may be equal to a distance (e.g., L2 of FIG. 7) by which the second cut pattern GC2 and the third cut pattern GC3 are spaced apart from each other in the second direction Y.

In some embodiments, the first cut pattern GC1 and the third cut pattern GC3 may define a unit cell region in the second direction Y.

A first source/drain region 161 may be formed in the first active pattern AP1 on the side faces of the first to sixth gate structures XG1 to XG4, G1, and G2. The bridge patterns 111 to 114 of the first active pattern AP1 penetrate the gate electrode 130 and the gate spacer 140, and may be connected to the first source/drain region 161. The first source/drain region 161 may be separated from the gate electrode 130 by the gate dielectric film 120, the gate spacer 140 and/or the inner spacer 145.

A second source/drain region 162 may be formed in the second active pattern AP2 on the side faces of the first to sixth gate structures XG1 to XG4, G1, and G2. The bridge patterns 111 to 114 of the second active pattern AP2 penetrate the gate electrode 130 and the gate spacer 140, and may be connected to the second source/drain region 162. The second source/drain region 162 may be separated from the gate electrode 130 by the gate dielectric film 120, the gate spacer 140, and/or the inner spacer 145.

In some embodiments, the first and second source/drain regions 161 and 162 may each include an epitaxial layer doped with impurities. For example, the first source/drain region 161 may include an epitaxial pattern grown from the first active pattern AP1 by an epitaxial growth method. For example, the second source/drain region 162 may include an epitaxial pattern grown from the second active pattern AP2 by the epitaxial growth method.

When the first active pattern AP1 is a channel region of an NFET, the first source/drain region 161 may include an N-type impurity (e.g., P, Sb or As) or an impurity for preventing diffusion of the N-type impurity.

When the second active pattern AP2 is a channel region of a PFET, the second source/drain region 162 may include a P-type impurity (e.g., B, In, Ga or Al) or an impurity for preventing diffusion of the P-type impurity.

The first interlayer insulating film ID1 may be formed on the first to sixth gate structures XG1 to XG4, G1, and G2 and the first and second source/drain regions 161 and 162. The first interlayer insulating film ID1 may fill spaces on the outer side faces of the first to sixth gate structures XG1 to XG4, G1, and G2, and cover the first and second source/drain regions 161 and 162. The second interlayer insulating film ID2 may be formed on the first to sixth gate structures XG1 to XG4, G1, and G2 and the first interlayer insulating film ID1.

The first interlayer insulating film ID1 and the second interlayer insulating film ID2 may each include, but not limited to, at least one of silicon oxide, silicon nitride, silicon oxynitride, silicon oxycarbide, silicon boron nitride, silicon boron carbonitride, silicon oxycarbon nitride, and a low dielectric constant material having a dielectric constant smaller than that of silicon oxide.

The wiring region WR may be stacked on the element region DR in the third direction Z. The wiring region WR may include first level wiring patterns M1 and second level wiring patterns M2. For example, the inter-wiring insulating film 200 may be formed on the second interlayer insulating film ID2. The first level wiring patterns M1 and the second level wiring patterns M2 may be formed in the inter-wiring insulating film 200 to form an electrical path.

The second level wiring patterns M2 may be disposed at an upper level than the first level wiring patterns M1. The expression disposed “at the upper level” in the wiring region WR means disposed away from the substrate 100 in the third direction Z. For example, as shown, the first level wiring patterns M1 may be disposed at a first level, and the second level wiring patterns M2 may be disposed at a second level higher than the first level, on the basis of the upper face of the substrate 100.

In some embodiments, the first level wiring patterns M1 may include a first power supply wiring 210a, a second power supply wiring 210b, and first to ninth lower wiring patterns 211a, 211b, 212a, 212b, 213a, 213b, 214a, 214b, and 214c.

The first power supply wiring 210a and the second power supply wiring 210b may each extend long in the first direction X. The first power supply wiring 210a and the second power supply wiring 210b may be spaced apart from each other in the second direction Y. A first power supply voltage (for example, V_{SS}) may be applied to the first power supply wiring 210a, and a second power supply voltage (for example, V_{DD}) different from the first power supply voltage may be applied to the second power supply wiring 210b.

Each of the first to ninth lower wiring patterns 211a, 211b, 212a, 212b, 213a, 213b, 214a, 214b, and 214c may extend long in the first direction X. The first to ninth lower wiring patterns 211a, 211b, 212a, 212b, 213a, 213b, 214a, 214b, and 214c may be disposed between the first power supply wiring 210a and the second power supply wiring 210b. In some embodiments, first to fourth routing tracks I to IV may be defined between the first power supply wiring 210a and the second power supply wiring 210b. The first to fourth routing tracks I to IV may be arranged sequentially along the second direction Y. Each of the first to fourth routing tracks I to IV may extend long in the first direction X.

The first and second lower wiring patterns 211a and 211b may be disposed in a first routing track I. The first and second lower wiring patterns 211a and 211b may be arranged sequentially along the first direction X, and may be spaced apart from each other in the first direction X.

The third and fourth lower wiring patterns 212a and 212b may be disposed in a second routing track II. The third and fourth lower wiring patterns 212a and 212b may be arranged sequentially along the first direction X, and may be spaced apart from each other in the first direction X.

In some embodiments, the wiring patterns in the second routing track II (e.g., the third or fourth lower wiring patterns 212a and 212b) may not completely intersect the first gate structure XG1 and/or the second gate structure XG2. For example, as shown in FIG. 1, one end of the first gate structure XG1 and/or one end of the second gate structure XG2 may overlap the fourth lower wiring pattern 212b in the third direction Z. Alternatively, unlike the shown example, the first gate structure XG1 and/or the second gate structure XG2 may not overlap the fourth lower wiring pattern 212b in the third direction Z.

The fifth and sixth lower wiring patterns 213a and 213b may be disposed in the third routing track III. The fifth and sixth lower wiring patterns 213a and 213b may be arranged sequentially along the first direction X, and may be spaced apart from each other in the first direction X.

In some embodiments, the wiring patterns in the third routing track III (e.g., the fifth or sixth lower wiring patterns 213a and 213b) may not completely intersect the third gate structure XG3 and/or the fourth gate structure XG4. For example, as shown in FIG. 1, one end of the third gate structure XG3 and/or one end of the fourth gate structure XG4 may overlap the fifth lower wiring pattern 213a in the third direction Z. Alternatively, unlike the shown example, the third gate structure XG3 and/or the fourth gate structure XG4 may not overlap the fifth lower wiring pattern 213a in the third direction Z.

Seventh to ninth lower wiring patterns 214a to 214c may be disposed in a fourth routing track IV. The seventh to ninth lower wiring patterns 214a to 214c may be arranged sequentially along the first direction X, and may be spaced apart from one another in the first direction X.

The first lower wiring pattern 211a may be connected to the first gate structure XG1. For example, a first gate contact 191 which penetrates the second interlayer insulating film ID2 and the gate capping film 150 and comes into contact with the gate electrode 130 of the first gate structure XG1 may be formed. The first lower wiring pattern 211a may be electrically connected to the first gate structure XG1 through the first gate contact 191.

The second lower wiring pattern 211b may be connected to the second gate structure XG2. For example, a second gate contact 192 which penetrates the second interlayer insulating film ID2 and the gate capping film 150 and comes into contact with the gate electrode 130 of the second gate structure XG2 may be formed. The second lower wiring pattern 211b may be electrically connected to the second gate structure XG2 through the second gate contact 192.

A seventh lower wiring pattern 214a may be connected to the third gate structure XG3. For example, a third gate contact 193 which penetrates the second interlayer insulating film ID2 and the gate capping film 150 and comes into contact with the gate electrode 130 of the third gate structure XG3 may be formed. The seventh lower wiring pattern 214a may be electrically connected to the third gate structure XG3 through the third gate contact 193.

An eighth lower wiring pattern 214b may be connected to the fourth gate structure XG4. For example, a fourth gate contact 194 which penetrates the second interlayer insulating film ID2 and the gate capping film 150 and comes into contact with the gate electrode 130 of the fourth gate structure XG4 may be formed. The eighth lower wiring pattern 214b may be electrically connected to the fourth gate structure XG4 through the fourth gate contact 194.

In some embodiments, the third lower wiring pattern 212a may be connected to the fifth gate structure G1. For example, a fifth gate contact 195 which connects the gate electrode 130 of the fifth gate structure G1 to the third lower wiring pattern 212a may be formed.

In some embodiments, the sixth lower wiring pattern 213b may be connected to the sixth gate structure G2. For example, a sixth gate contact 196 which connects the gate electrode 130 of the sixth gate structure G2 and the sixth lower wiring pattern 213b may be formed.

The second level wiring patterns M2 may include a first upper wiring pattern 231 and a second upper wiring pattern 232.

The first upper wiring pattern 231 may include a first extension 231x and a second extension 231y. The first extension 231x may extend long in the first direction X. The second extension 231y may extend long from the first extension 231x in the second direction Y. In some embodiments, as shown in FIG. 1, the first extension 231x and the second extension 231y may form a generally L-shaped first upper wiring pattern 231 from a planar point of view parallel to the upper face of the substrate 100.

The first upper wiring pattern 231 may connect the second lower wiring pattern 211b and the seventh lower wiring pattern 214a. For example, a first via pattern 221 that connects the second lower wiring pattern 211b and the first extension 231x may be formed in the inter-wiring insulating film 200. Also, for example, a second via pattern 222 that connects the seventh lower wiring pattern 214a and the second extension 231y may be formed in the inter-wiring insulating film 200.

Accordingly, the second gate structure XG2 and the third gate structure XG3 may be electrically connected to each other. Specifically, as shown in FIG. 7, the second gate contact 192, the second lower wiring pattern 211b, the first via pattern 221, the first upper wiring pattern 231, the second via pattern 222, the seventh lower wiring pattern 214a, and the third gate contact 193 may form a first electrical path EP1 that connects the second gate structure XG2 and the third gate structure XG3.

In some embodiments, the first extension 231x may overlap the first lower wiring pattern 211a and the second lower wiring pattern 211b in the third direction Z.

In some embodiments, the second extension 231y may be disposed between the first gate structure XG1 and the fifth gate structure G1, and between the third gate structure XG3 and the fifth gate structure G1 from a planar point of view parallel to the upper face of the substrate 100.

The second upper wiring pattern 232 may extend long in the second direction Y. The second upper wiring pattern 232 may connect the fifth lower wiring pattern 213a and the eighth lower wiring pattern 214b. For example, a third via pattern 223 that connects the fifth lower wiring pattern 213a and the second upper wiring pattern 232 may be formed in the inter-wiring insulating film 200. Also, for example, a fourth via pattern 224 that connects the eighth lower wiring pattern 214b and the second upper wiring pattern 232 may be formed in the inter-wiring insulating film 200.

In some embodiments, the second upper wiring pattern 232 may overlap the fourth gate structure XG4 in the third direction Z.

In some embodiments, the first via pattern 221, the third via pattern 223, and the fourth via pattern 224 may be arranged in a line along the second direction Y. For example, the first via pattern 221 may overlap the second gate structure XG2 in the third direction Z, and each of the third via pattern 223 and the fourth via pattern 224 may overlap the fourth gate structure XG4 in the third direction Z.

In some embodiments, a first wiring pitch MP1 at which the second extension 231y of the first upper wiring pattern 231 and the second upper wiring pattern 232 are arranged may be larger than 1 GP (gate pitch). Here, the first wiring pitch MP1 may be defined as the sum of the interval between the adjacent upper wiring patterns (e.g., the second extension 231y of the first upper wiring pattern 231 and the second upper wiring pattern 232) in the first direction X and the width of one (e.g., the second extension 231y) of them. The width of the second extension 213y may be defined in the first direction X. The GP (gate pitch) means a unit placement interval between the gate structures arranged along the first direction X. For example, as shown in FIGS. 7, 1 GP may be defined as the sum of the interval between the adjacent gate structures (e.g., the first gate structure XG1 and the second gate structure XG2) in the first direction X and the width of one (e.g., the first gate structure XG1) of them. Alternatively, for example, 1 GP may be defined as an interval between the center line of one gate structure (e.g., the first gate structure XG1) and the center line of another gate structure (e.g., the second gate structure XG2) adjacent thereto.

The fifth lower wiring pattern 213a may be electrically connected to the first lower wiring pattern 211a. For example, a first connecting pattern CP1 extending in the second direction Y may be formed. In some embodiments, the first connecting pattern CP1 is formed in the first interlayer insulating film ID1, and may be connected to the first source/drain region 161. For example, the first connecting pattern CP1 may come into contact with the first source/drain region 161 on the side face of the fifth gate structure G1. In some embodiments, the first connecting pattern CP1 may connect the first source/drain region 161 and the second source/drain region 162. For example, as shown in FIGS. 1 and 6, the first connecting pattern CP1 may come into contact with both the first source/drain region 161 and the second source/drain region 162.

The first connecting pattern CP1 may electrically connect the first lower wiring pattern 211a and the fifth lower wiring pattern 213a. For example, a first via contact 181 which penetrates the second interlayer insulating film ID2 to connect the first lower wiring pattern 211a and the first connecting pattern CP1 may be formed. Also, for example, a second via contact 182 which penetrates the second interlayer insulating film ID2 to connect the fifth lower wiring pattern 213a and the first connecting pattern CP1 may be formed.

Accordingly, the first gate structure XG1 and the fourth gate structure XG4 may be electrically connected to each other. Specifically, as shown in FIG. 7, the first gate contact 191, the first lower wiring pattern 211a, the first via contact 181, the first connecting pattern CP1, the second via contact 182, the fifth lower wiring pattern 213a, the third via pattern 223, the second upper wiring pattern 232, the fourth via pattern 224, the eighth lower wiring pattern 214b and the fourth gate contact 194 may form a second electrical path EP2 that connects the first gate structure XG1 and the fourth gate structure XG4.

In the design of the semiconductor device, a so-called cross-gate connection structure in which two pairs of gates are cross-connected may be required. However, as the high integration of the semiconductor devices is continuously required, the use of the wiring of the upper level (e.g., the second level or higher) is increasing to realize the cross-gate connection structure. To avoid this problem, an additional routing track that intersects the relatively long gate may be utilized by cutting the gates asymmetrically in a height direction of the cell (e.g., the second direction Y). However, this causes an increase in process difficulty.

The semiconductor device according to some embodiments may provide a simple cross-gate connection structure, by using the first upper wiring pattern 231 and the second upper wiring pattern 232. Specifically, as described above, the first upper wiring pattern 231 is formed generally in an L-shape, and may form the first electrical path EP1 that connects the second gate structure XG2 and the third gate structure XG3. In addition, the second upper wiring pattern 232 may form a second electrical path EP2 that connects the first gate structure XG1 and the fourth gate structure XG4 even without asymmetrically cutting the gates (first to fourth gate structures XG1 to XG4), by providing a connection path with a routing track (e.g., the second routing track II or the third routing track III) that does not completely intersect the gates (first to fourth gate structures XG1 to XG4). Accordingly, it is possible to provide a semiconductor device with improved performance, by reducing the use of wiring of the upper level (e.g., the second level or higher) even for gates (first to fourth gate structures XG1 to XG4) that are symmetric in the cell height direction (the second direction Y).

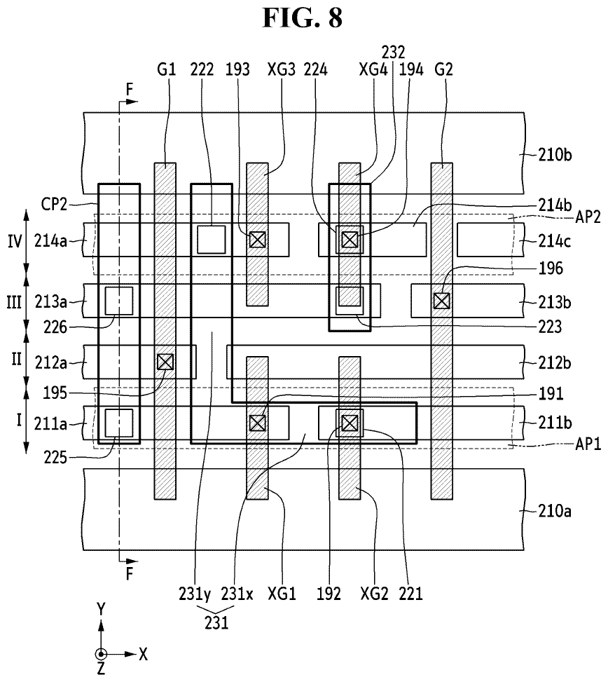

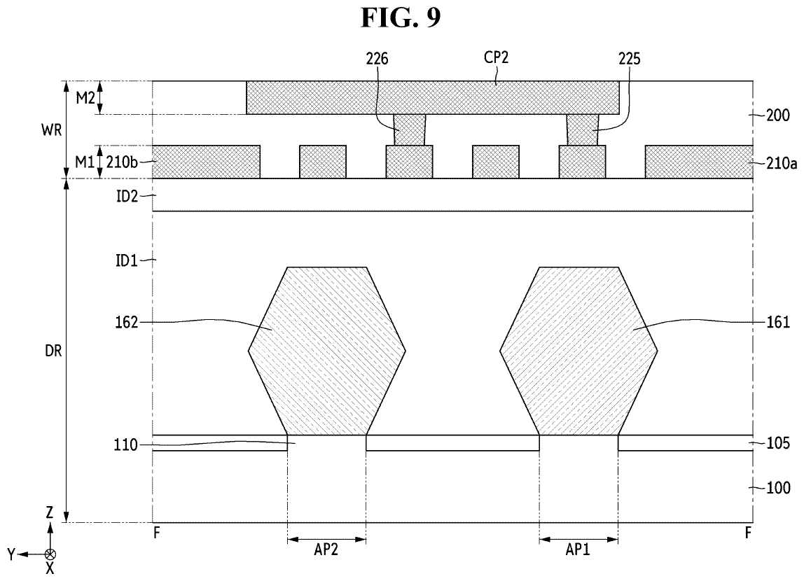

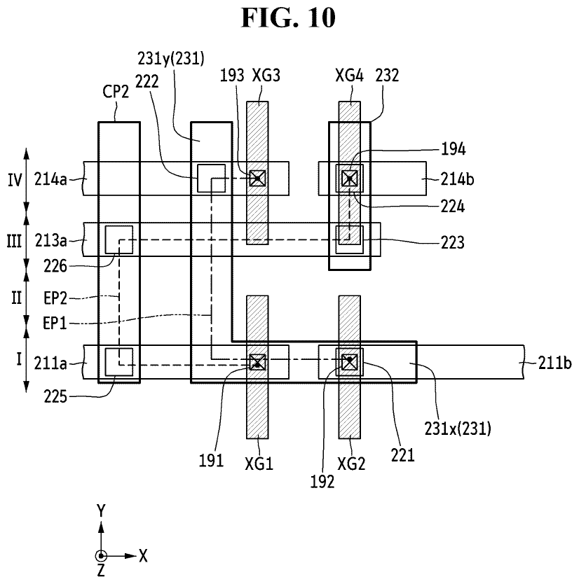

FIG. 8 is an exemplary layout diagram for explaining a semiconductor device according to some embodiments. FIG. 9 is a cross-sectional view taken along F-F of FIG. 8 according to some embodiments. FIG. 10 is a partial layout diagram for explaining the cross-gate connection structure of the semiconductor device of FIG. 8. according to some embodiments For convenience of explanation, repeated parts of contents explained above using FIGS. 1 to 7 will be briefly explained or omitted.

Referring to FIGS. 8 to 10, in the semiconductor device according to some embodiments, the second level wiring pattern M2 further includes a second connecting pattern CP2.

The second connecting pattern CP2 may extend in the second direction Y and connect the first lower wiring pattern 211a and the fifth lower wiring pattern 213a. For example, a fifth via pattern 225 that connects the first lower wiring pattern 211a and the second connecting pattern CP2 may be formed in the inter-wiring insulating film 200. Also, for example, a sixth via pattern 226 that connects the fifth lower wiring pattern 213a and the second connecting pattern CP2 may be formed in the inter-wiring insulating film 200.

Accordingly, the first gate structure XG1 and the fourth gate structure XG4 may be electrically connected to each other. Specifically, as shown in FIG. 10, the first gate contact 191, the first lower wiring pattern 211a, the fifth via pattern 225, the second connecting pattern CP2, the sixth via pattern 226, the fifth lower wiring pattern 213a, the third via pattern 223, the second upper wiring pattern 232, the fourth via pattern 224, the eighth lower wiring pattern 214b, and the fourth gate contact 194 may form a second electrical path EP2 that connects the first gate structure XG1 and the fourth gate structure XG4.

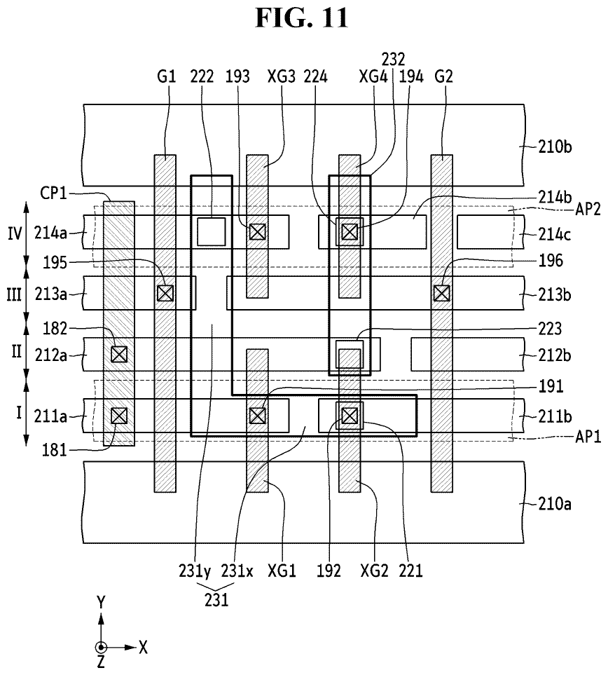

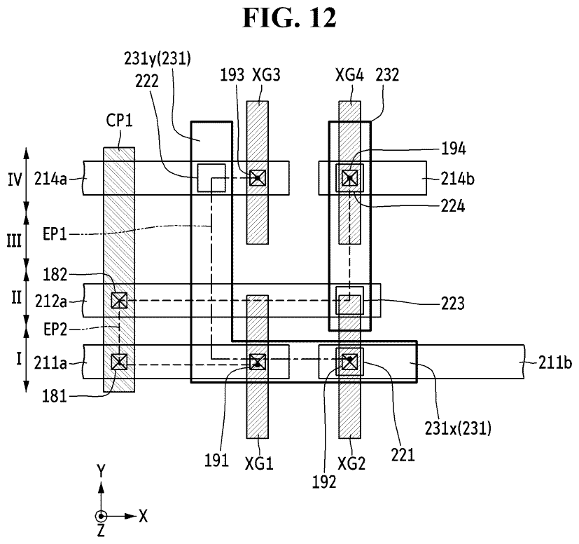

FIG. 11 is an exemplary layout diagram for explaining a semiconductor device according to some embodiments. FIG. 12 is a partial layout diagram for explaining a cross-gate connection structure of the semiconductor device of FIG. 11 according to some embodiments. For convenience of explanation, repeated parts of contents explained above referring to FIGS. 1 to 7 will be briefly explained or omitted.

Referring to FIGS. 11 and 12, in the semiconductor device according to some embodiments, the second upper wiring pattern 232 extends in the second direction Y and connects the third lower wiring pattern 212a and the eighth lower wiring pattern 214b. For example, the third via pattern 223 may connect the third lower wiring pattern 212a and the second upper wiring pattern 232.

The first connecting pattern CP1 may extend in the second direction Y and connect the first lower wiring pattern 211a and the third lower wiring pattern 212a. For example, the second via contact 182 may connect the third lower wiring pattern 212a and the first connecting pattern CP1.

Accordingly, the first gate structure XG1 and the fourth gate structure XG4 may be electrically connected to each other. Specifically, as shown in FIG. 12, the first gate contact 191, the first lower wiring pattern 211a, the first via contact 181, the first connecting pattern CP1, the second via contact 182, the third lower wiring pattern 212a, the third via pattern 223, the second upper wiring pattern 232, the fourth via pattern 224, the eighth lower wiring pattern 214b, and the fourth gate contact 194 may form a second electrical path EP2 that connects the first gate structure XG1 and the fourth gate structure XG4.

Although the first lower wiring pattern 211a and the third lower wiring pattern 212a are only described as being connected by the first connecting pattern CP1, this is merely exemplary, and it goes without saying that the first lower wiring pattern 211a and the third lower wiring pattern 212a may be connected by the second connecting pattern CP2 described above using FIGS. 8 to 10.

In some embodiments, the fifth gate contact 195 may connect the fifth gate structure G1 and the fifth lower wiring pattern 213a.

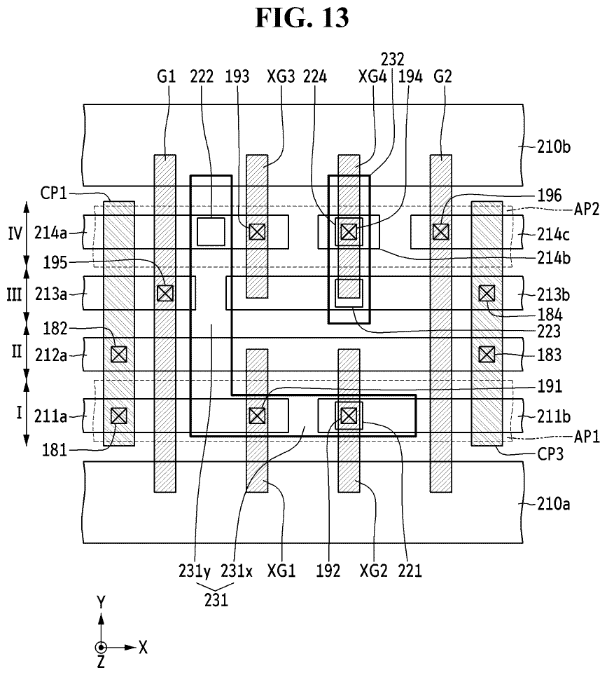

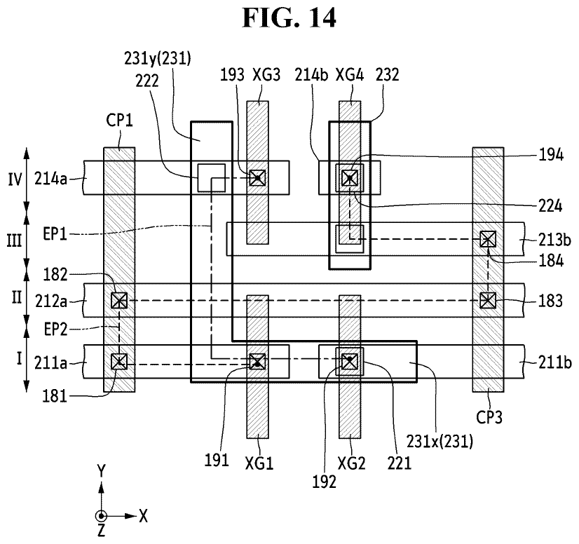

FIG. 13 is an exemplary layout diagram for explaining a semiconductor device according to some embodiments. FIG. 14 is a partial layout diagram for explaining the cross-gate connection structure of the semiconductor device of FIG. 13 according to some embodiments. For convenience of explanation, repeated parts of contents explained above referring to FIGS. 1 to 7 will be briefly explained or omitted.

Referring to FIGS. 13 and 14, in the semiconductor device according to some embodiments, the second upper wiring pattern 232 extends in the second direction Y and connects the sixth lower wiring pattern 213b and the eighth lower wiring pattern 214b. For example, the third via pattern 223 may connect the sixth lower wiring pattern 213b and the second upper wiring pattern 232.

The sixth lower wiring pattern 213b may be electrically connected to the third lower wiring pattern 212a. For example, a third connecting pattern CP3 extending in the second direction Y may be formed. Because the third connecting pattern CP3 may be similar to the first connecting pattern CP1, the detailed description will not be provided below.

The third connecting pattern CP3 may electrically connect the third lower wiring pattern 212a and the sixth lower wiring pattern 213b. For example, a third via contact 183 that connects the third lower wiring pattern 212a and the third connecting pattern CP3 may be formed. Also, for example, a fourth via contact 184 that connects the sixth lower wiring pattern 213b and the third connecting pattern CP3 may be formed.

The first connecting pattern CP1 may extend in the second direction Y and connect the first lower wiring pattern 211a and the third lower wiring pattern 212a. For example, the second via contact 182 may connect the third lower wiring pattern 212a and the first connecting pattern CP1.

Accordingly, the first gate structure XG1 and the fourth gate structure XG4 may be electrically connected to each other. Specifically, as shown in FIG. 14, the first gate contact 191, the first lower wiring pattern 211a, the first via contact 181, the first connecting pattern CP1, the second via contact 182, the third lower wiring pattern 212a, the third via contact 183, the third connecting pattern CP3, the fourth via contact 184, the sixth lower wiring pattern 213b, the third via pattern 223, the second upper wiring pattern 232, the fourth via pattern 224, the eighth lower wiring pattern 214b, and the fourth gate contact 194 may form a second electrical path EP2 that connects the first gate structure XG1 and the fourth gate structure XG4.

Although the first lower wiring pattern 211a and the third lower wiring pattern 212a are only described as being connected by the first connecting pattern CP1, this is merely exemplary, and it goes without saying that the first lower wiring pattern 211a and the third lower wiring pattern 212a may be connected by the second connecting pattern CP2 described above using FIGS. 8 to 10. Similarly, the third lower wiring pattern 212a and the sixth lower wiring pattern 213b may also be connected by the second level wiring patterns M2.

In some embodiments, the fifth gate contact 195 may connect the fifth gate structure G1 and the fifth lower wiring pattern 213a.

In some embodiments, the sixth gate contact 196 may connect the sixth gate structure G2 and the ninth lower wiring pattern 214c.

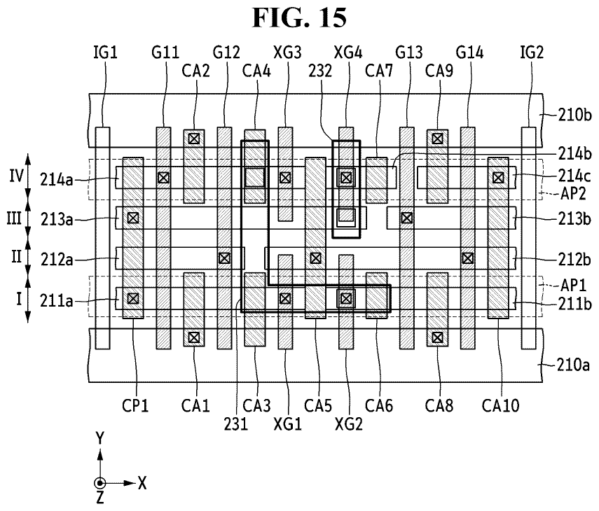

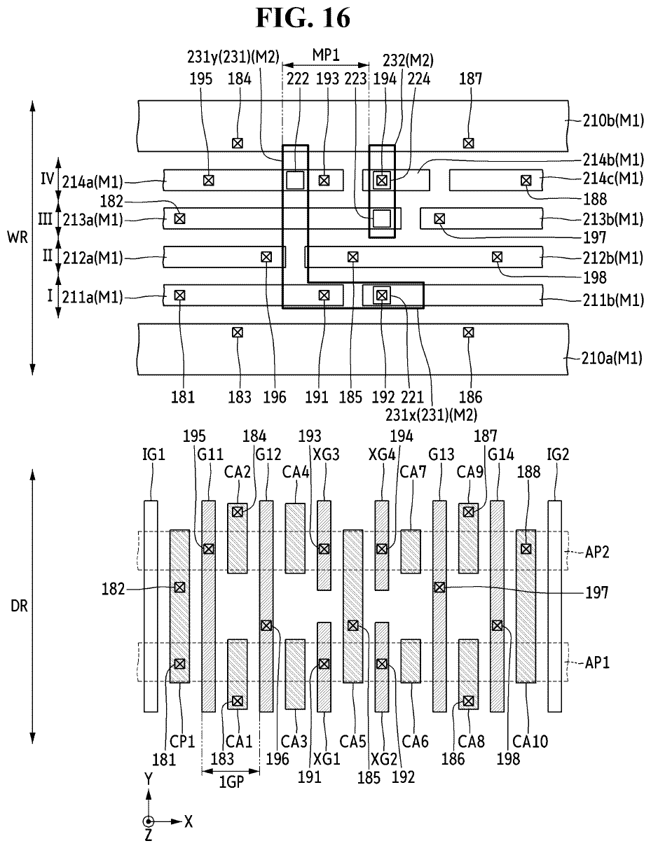

FIGS. 15 and 16 are exemplary layout diagrams for explaining a semiconductor device according to some embodiments. For convenience of explanation, repeated parts of contents explained above referring to FIGS. 1 to 14 will be briefly explained or omitted. For reference, FIG. 16 shows the element region DR and the wiring region WR to be separated from each other in the semiconductor device of FIG. 15 according to some embodiments.

FIGS. 15 and 16 show a multiplexer (MUX) cell as a standard cell in which the cross-gate connection structure is used, but the present invention is not limited thereto. A person having ordinary knowledge in the technical field to which the present inventive concept pertains will understand that the present inventive concept may be implemented in various other cells in which the cross-gate connection structure may be used.

Referring to FIGS. 15 and 16, in the semiconductor device according to some embodiments, the element region DR may include first and second active patterns AP1 and AP2, first to fourth gate structures XG1 to XG4, seventh to tenth gate structures G11 to G14, first and second separation structures IG1 and IG2, and first to tenth source/drain contacts CA1 to CA10.

Each of the seventh to tenth gate structures G11 to G14 may extend long in the second direction Y. The seventh to tenth gate structures G11 to G14 may be spaced apart from one another and arranged sequentially in the first direction X. The first to fourth gate structures XG1 to XG4 may be disposed between the eighth gate structure G12 and the ninth gate structure G13. Each of the seventh to tenth gate structures G11 to G14 may intersect the first active pattern AP1 and the second active pattern AP2. Because each of the seventh to tenth gate structures G11 to G14 may be similar to the fifth gate structure G1 or the sixth gate structure G2 described above using FIGS. 1 to 7, detailed description thereof will not be provided below.

In some embodiments, the seventh lower wiring pattern 214a may be connected to the seventh gate structure G11. For example, a fifth gate contact 195 that connects the gate electrode 130 of the seventh gate structure G11 and the seventh lower wiring pattern 214a may be formed.

In some embodiments, the third lower wiring pattern 212a may be connected to the eighth gate structure G12. For example, a sixth gate contact 196 that connects the gate electrode 130 of the eighth gate structure G12 and the third lower wiring pattern 212a may be formed.

In some embodiments, the sixth lower wiring pattern 213b may be connected to the ninth gate structure G13. For example, a seventh gate contact 197 that connects the gate electrode 130 of the ninth gate structure G13 and the sixth lower wiring pattern 213b may be formed.

In some embodiments, the fourth lower wiring pattern 212b may be connected to a tenth gate structure G14. For example, an eighth gate contact 198 that connects the gate electrode 130 of the tenth gate structure G14 and the fourth lower wiring pattern 212b may be formed.

In some embodiments, the first to eighth gate contacts 191 to 198 may be formed at the same level as each other. In this specification, the expression “formed at the same level” means formation by the same fabricating process.

Each of the first and second separation structures IG1 and IG2 may extend long in the second direction Y. The first and second separation structures IG1 and IG2 may be spaced apart from each other and arranged sequentially in the first direction X. The first to fourth gate structures XG1 to XG4 and the seventh to tenth gate structures G11 to G14 may be disposed between the first separation structure IG1 and the second separation structure IG2.

Each of the first and second separation structures IG1 and IG2 may include an insulating material, for example, but not limited to, at least one of silicon oxide, silicon nitride, silicon oxynitride, silicon oxycarbide, silicon boron nitride, silicon boron carbonitride, silicon oxycarbon nitride, and combinations thereof.

In some embodiments, the first separation structure IG1 and the second separation structure IG2 may define a unit cell region in the first direction X.

The first to tenth source/drain contacts CA1 to CA10 may be connected to the first source/drain region 161 of the first active pattern AP1 and/or the second source/drain region 162 of the second active pattern AP2. Therefore, the first to tenth source/drain contacts CA1 to CA10 may be electrically connected to the first active pattern AP1 and/or the second active pattern AP2. The shape, placement, and the like of the first to tenth source/drain contacts CA1 to CA10 are merely exemplary, and are not limited to those shown in the drawings.

A first source/drain contact CA1 may be interposed between the seventh gate structure G11 and the eighth gate structure G12. The first source/drain contact CA1 may connect the first active pattern AP1 and the first power supply wiring 210a. For example, a third via contact 183 which connects the first source/drain contact CA1 and the first power supply wiring 210a may be formed.

A second source/drain contact CA2 may be interposed between the seventh gate structure G11 and the eighth gate structure G12. The second source/drain contact CA2 may connect the second active pattern AP2 and the second power supply wiring 210b. For example, a fourth via contact 184 that connects the second source/drain contact CA2 and the second power supply wiring 210b may be formed.

A third source/drain contact CA3 may be interposed between the first gate structure XG1 and the eighth gate structure G12. The third source/drain contact CA3 may be connected to the first active pattern AP1.

A fourth source/drain contact CA4 may be interposed between the third gate structure XG3 and the eighth gate structure G12. The fourth source/drain contact CA4 may be connected to the second active pattern AP2.

A fifth source/drain contact CA5 may be interposed between the first gate structure XG1 and the second gate structure XG2, and between the third gate structure XG3 and the fourth gate structure XG4. The fifth source/drain contact CA5 extends in the second direction Y and may connect the first active pattern AP1 and the second active pattern AP2.

In some embodiments, the fifth source/drain contact CA5 may be connected to the fourth lower wiring pattern 212b. For example, a fifth via contact 185 that connects the fifth source/drain contact CA5 and the fourth lower wiring pattern 212b may be formed.

A sixth source/drain contact CA6 may be interposed between the second gate structure XG2 and the ninth gate structure G13. The sixth source/drain contact CA6 may be connected to the first active pattern AP1.

A seventh source/drain contact CA7 may be interposed between the fourth gate structure XG4 and the ninth gate structure G13. The seventh source/drain contact CA7 may be connected to the second active pattern AP2.

An eighth source/drain contact CA8 may be interposed between the ninth gate structure G13 and the tenth gate structure G14. The eighth source/drain contact CA8 may connect the first active pattern AP1 and the first power supply wiring 210a. For example, a sixth via contact 186 which connects the eighth source/drain contact CA8 and the first power supply wiring 210a may be formed.

A ninth source/drain contact CA9 may be interposed between the ninth gate structure G13 and the tenth gate structure G14. The ninth source/drain contact CA9 may connect the second active pattern AP2 and the second power supply wiring 210b. For example, a seventh via contact 187 which connects the ninth source/drain contact CA9 and the second power supply wiring 210b may be formed.

A tenth source/drain contact CA10 may be interposed between the tenth gate structure G14 and the second separation structure IG2. The tenth source/drain contact CA10 extends in the second direction Y and may connect the first active pattern AP1 and the second active pattern AP2.

In some embodiments, the tenth source/drain contact CA10 may be connected to the ninth lower wiring pattern 214c. For example, an eighth via contact 188 which connects the tenth source/drain contact CA10 and the ninth lower wiring pattern 214c may be formed.

In some embodiments, the first connecting pattern CP1 may be interposed between the first separation structure IG1 and the seventh gate structure G11.

In some embodiments, the first connecting pattern CP1 may be formed at the same level as the first to tenth source/drain contacts CA1 to CA10.

In some embodiments, the first to eighth via contacts 181 to 188 may be formed at the same level as each other.

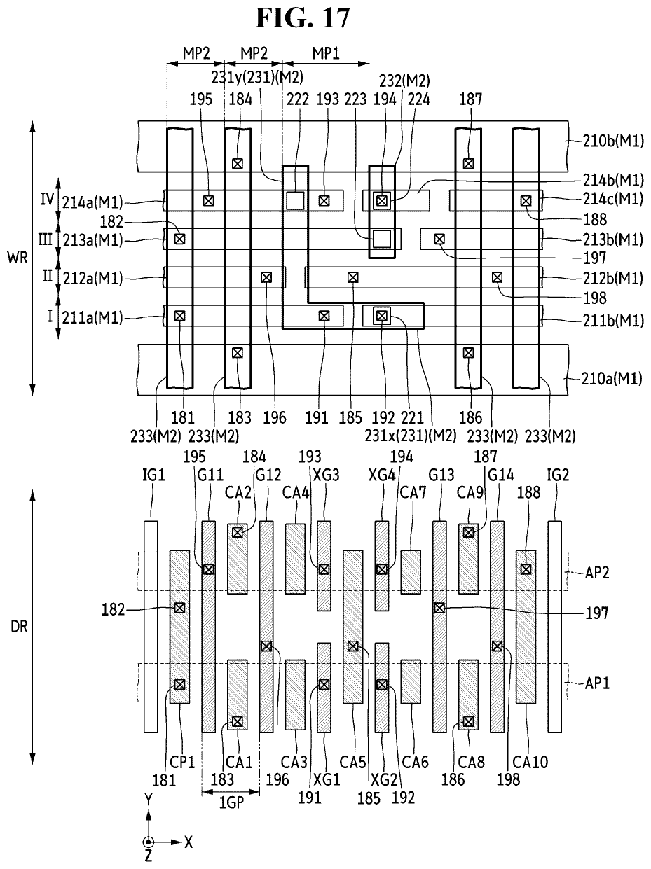

FIGS. 17 to 22 are various exemplary layout diagrams for explaining a semiconductor device according to some embodiments. For convenience of explanation, repeated parts of contents explained above using FIGS. 1 to 16 will be briefly explained or omitted.

Referring to FIGS. 17 to 19, in the semiconductor device according to some embodiments, the second level wiring patterns M2 further include a plurality of third upper wiring patterns 233.

Each of the plurality of third upper wiring patterns 233 may extend long in the second direction Y. The plurality of third upper wiring patterns 233 may be spaced apart from each other in the first direction X. The plurality of third upper wiring patterns 233 may be spaced apart from the first upper wiring pattern 231 and the second upper wiring pattern 232 in the first direction X.

The plurality of third upper wiring patterns 233 may be arranged at a second wiring pitch MP2 in the first direction X. In some embodiments, the second extension 231y of the first upper wiring pattern 231 and one third upper wiring pattern 233 adjacent thereto may be arranged at a second wiring pitch MP2. In some embodiments, the second wiring pitch MP2 may be equal to 1 nGP. That is, a gear ratio between the gate structures XG1 to XG4 and G11 to G14 and the second level wiring patterns M2 may be 1:1.

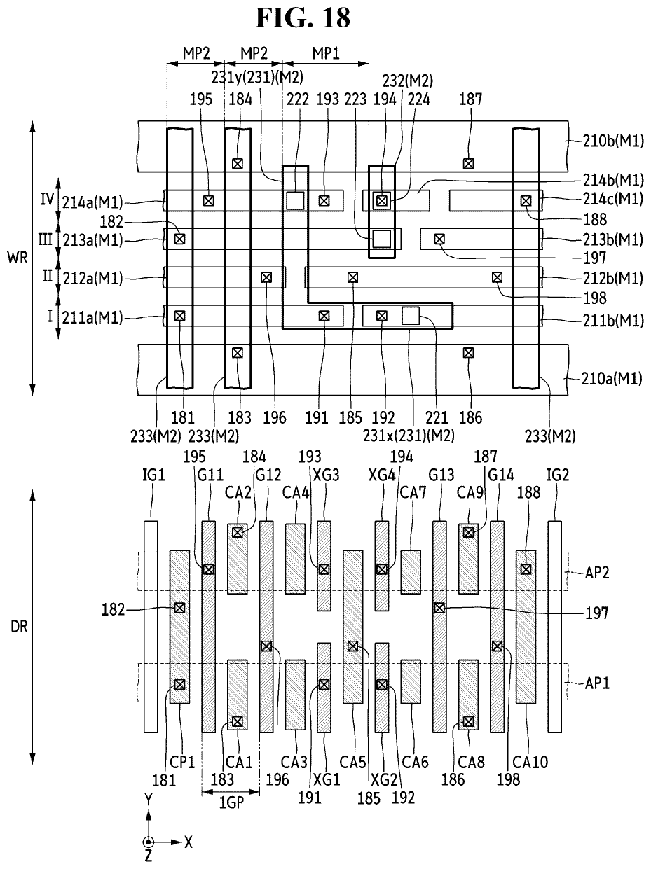

Referring to FIG. 18, in the semiconductor device according to some embodiments, the first via pattern 221 is disposed between the second gate structure XG2 and the ninth gate structure G13 from a planar point of view parallel to the upper face of the substrate 100.

For example, the first via pattern 221 may overlap the sixth source/drain contact CA6 in the third direction Z. In this case, the first via pattern 221 may not be arranged along the second direction Y together with the third via pattern 223 and the fourth via pattern 224.

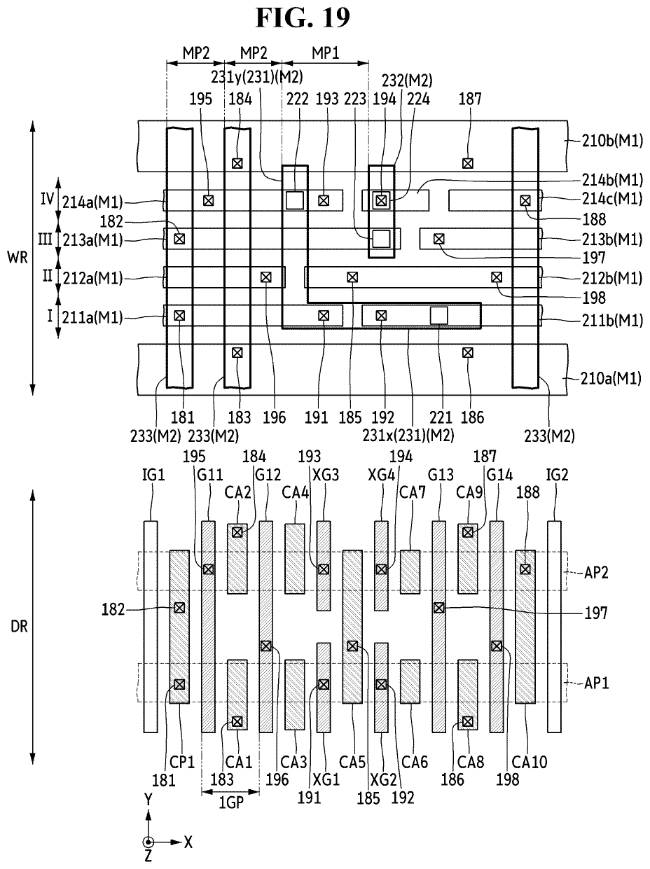

Referring to FIG. 19, in the semiconductor device according to some embodiments, the first via pattern 221 is disposed between the sixth source/drain contact CA6 and the eighth source/drain contact CA8 from a planar point of view parallel to the upper face of the substrate 100.

For example, the first via pattern 221 may overlap the ninth gate structure G13 in the third direction Z. In this case, the first via pattern 221 may not be arranged along the second direction Y together with the third via pattern 223 and the fourth via pattern 224.

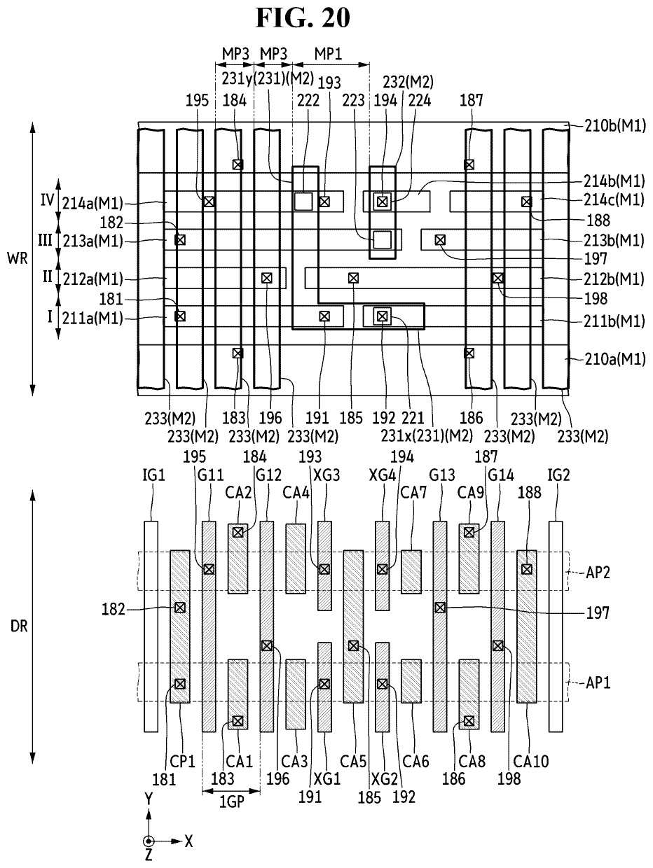

Referring to FIGS. 20 to 22, in the semiconductor device according to some embodiments, the second level wiring patterns M2 further include a plurality of third upper wiring patterns 233.

Each of the plurality of third upper wiring patterns 233 may extend long in the second direction Y. The plurality of third upper wiring patterns 233 may be spaced apart from each other in the first direction X. The plurality of third upper wiring patterns 233 may be spaced apart from the first upper wiring pattern 231 and the second upper wiring pattern 232 in the first direction X.

The plurality of third upper wiring patterns 233 may be arranged at a third wiring pitch MP3 in the first direction X. In some embodiments, the second extension 231y of the first upper wiring pattern 231 and one third upper wiring pattern 233 adjacent thereto may be arranged at the third wiring pitch MP3. In some embodiments, three times the third wiring pitch MP3 may be equal to 2 GP. That is, the gear ratio between the gate structures XG1 to XG4 and G11 to G14 and the second level wiring patterns M2 may be 2:3.

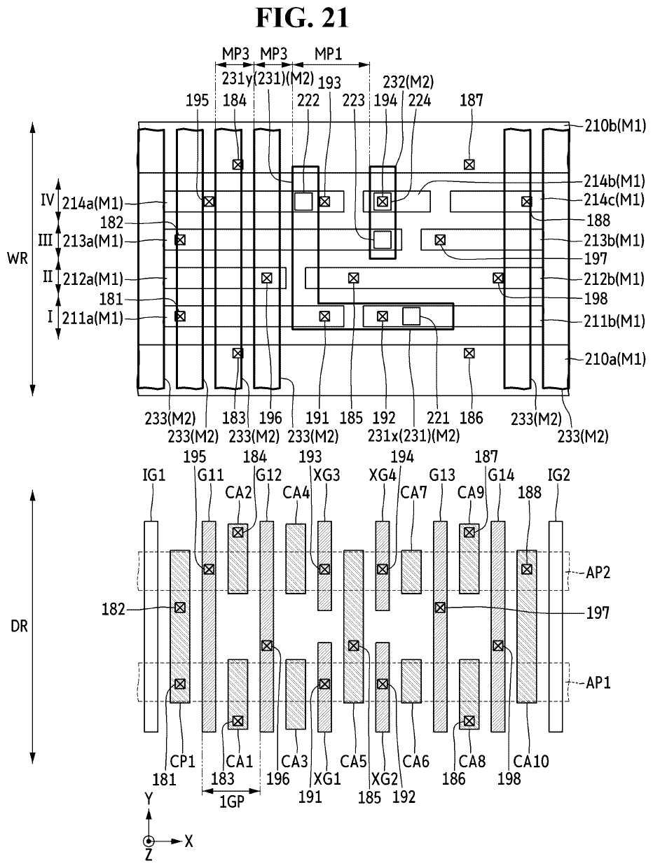

Referring to FIG. 21, in the semiconductor device according to some embodiments, the first via pattern 221 is disposed between the second gate structure XG2 and the ninth gate structure G13 from a planar point of view parallel to the upper face of the substrate 100.

For example, the first via pattern 221 may overlap the sixth source/drain contact CA6 in the third direction Z. In this case, the first via pattern 221 may not be arranged along the second direction Y together with the third via pattern 223 and the fourth via pattern 224.

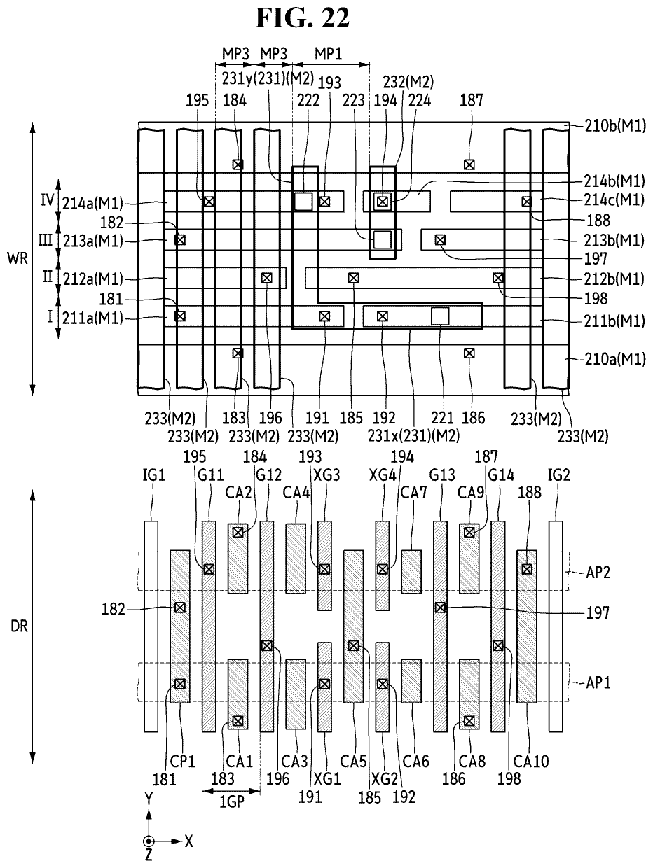

Referring to FIG. 22, in the semiconductor device according to some embodiments, the first via pattern 221 is disposed between the sixth source/drain contact CA6 and the eighth source/drain contact CA8 from a planar point of view parallel to the upper face of the substrate 100.

For example, the first via pattern 221 may overlap the ninth gate structure G13 in the third direction Z. In this case, the first via pattern 221 may not be arranged along the second direction Y together with the third via pattern 223 and the fourth via pattern 224.

While the present inventive concept has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A semiconductor device comprising:
a substrate;
a first active pattern which extends in a first direction on the substrate;
a second active pattern which is spaced apart from the first active pattern in a second direction intersecting the first direction, and extends in the first direction on the substrate;
a first gate structure which intersects the first active pattern;
a second gate structure which is spaced apart from the first gate structure in the first direction, and intersects the first active pattern;
a third gate structure which is spaced apart from the first gate structure in the second direction, and intersects the second active pattern;
a fourth gate structure which is spaced apart from the second gate structure in the second direction, and intersects the second active pattern;
first level wiring patterns which are disposed at a first level on the basis of an upper face of the substrate, and include first to fifth lower wiring patterns each extending in the first direction; and
second level wiring patterns which are disposed at a second level higher than the first level on the basis of the upper face of the substrate, and include a first upper wiring pattern and a second upper wiring pattern, wherein:
the first to fourth lower wiring patterns are connected to the first to fourth gate structures, respectively,
the fifth lower wiring pattern is interposed between the second lower wiring pattern and the fourth lower wiring pattern,
the first upper wiring pattern includes a first extension extending in the first direction and connected to the second lower wiring pattern, and a second extension extending in the second direction from the first extension and connected to the third lower wiring pattern,
the second upper wiring pattern extends in the second direction and connects the fourth lower wiring pattern and the fifth lower wiring pattern, and
the fifth lower wiring pattern is electrically connected to the first lower wiring pattern.

2. The semiconductor device of claim 1, wherein in a third direction intersecting the upper face of the substrate, the second gate structure does not overlap the fifth lower wiring pattern, or one end of the second gate structure overlaps the fifth lower wiring pattern.

3. The semiconductor device of claim 1, wherein lengths of the first to fourth gate structures are equal to each other in the second direction.

4. The semiconductor device of claim 1, wherein the first extension and the second extension form the first upper wiring pattern of an L shape from a planar point of view parallel to the upper face of the substrate.

5. The semiconductor device of claim 1, wherein the first extension overlaps the first lower wiring pattern and the second lower wiring pattern in a third direction intersecting the upper face of the substrate.

6. The semiconductor device of claim 1, wherein the second upper wiring pattern overlaps the first extension in the second direction and overlaps the second extension in the first direction.

7. The semiconductor device of claim 1, further comprising:
a connecting pattern which is connected to a source/drain region of the first active pattern, extends in the second direction, and connects the first lower wiring pattern and the fifth lower wiring pattern.

8. The semiconductor device of claim 1, wherein the second level wiring patterns further include a connecting pattern which extends in the second direction and connects the first lower wiring pattern and the fifth lower wiring pattern.

9. The semiconductor device of claim 1, wherein a wiring pitch at which the second extension and the second upper wiring pattern are spaced apart from each other in the first direction is greater than a gate pitch at which the first gate structure and the second gate structure are spaced apart from each other in the first direction,
wherein the wiring pitch is the sum of an interval between the second extension and the second upper wiring pattern and a width of the second extension in the first direction, and
wherein the gate pitch is the sum of an interval between the first gate structure and the second gate structure and a width of the first gate structure in the first direction.

10. The semiconductor device of claim 1, further comprising:
a first via pattern which connects the second lower wiring pattern and the first extension;
a second via pattern which connects the third lower wiring pattern and the second extension;
a third via pattern which connects the fourth lower wiring pattern and the second upper wiring pattern; and
a fourth via pattern which connects the fifth lower wiring pattern and the second upper wiring pattern.

11. A semiconductor device comprising:
a substrate;
a first active pattern which extends in a first direction on the substrate;
a second active pattern which is spaced apart from the first active pattern in a second direction intersecting the first direction, and extends in the first direction on the substrate;
a first gate structure which intersects the first active pattern;
a second gate structure which is spaced apart from the first gate structure in the first direction, and intersects the first active pattern;
a third gate structure which is spaced apart from the first gate structure in the second direction, and intersects the second active pattern;
a fourth gate structure which is spaced apart from the second gate structure in the second direction, and intersects the second active pattern;
first level wiring patterns which are disposed at a first level on the basis of an upper face of the substrate, the first level wiring patterns including a first power supply wiring and a second power supply wiring each extending in the first direction and spaced apart from each other in the second direction;
second level wiring patterns which are disposed at a second level higher than the first level on the basis of the upper face of the substrate, the second level wiring patterns including a first upper wiring pattern and a second upper wiring pattern;
a connecting pattern; and
first to fourth routing tracks which are arranged sequentially along the second direction and each extend in the first direction are defined between the first power supply wiring and the second power supply wiring, wherein:
the first level wiring patterns include a first lower wiring pattern connected to the first gate structure in the first routing track, a second lower wiring pattern connected to the second gate structure in the first routing track, a third lower wiring pattern connected to the third gate structure in the fourth routing track, a fourth lower wiring pattern connected to the fourth gate structure in the fourth routing track, and a fifth lower wiring pattern in the third routing track,
the first upper wiring pattern includes a first extension extending in the first direction and connected to the second lower wiring pattern, and a second extension extending in the second direction from the first extension and connected to the third lower wiring pattern,
the second upper wiring pattern extends in the second direction and connects the fourth lower wiring pattern and the fifth lower wiring pattern, and
the connecting pattern extends in the second direction and connects the first lower wiring pattern and the fifth lower wiring pattern.

12. The semiconductor device of claim 11, wherein in a third direction intersecting the upper face of the substrate, the second gate structure does not overlap the fifth lower wiring pattern, or one end of the second gate structure overlaps the fifth lower wiring pattern.

13. The semiconductor device of claim 11, further comprising:
a first cut pattern which overlaps the first power supply wiring in a third direction intersecting the upper face of the substrate, extends in the first direction, and cuts the first gate structure and the second gate structure;
a second cut pattern which extends in the first direction between the first active pattern and the second active pattern, separates the first gate structure and the third gate structure, and separates the second gate structure and the fourth gate structure; and
a third cut pattern which overlaps the second power supply wiring in the third direction, extends in the first direction, and cuts the third gate structure and the fourth gate structure.

14. The semiconductor device of claim 13, wherein a distance by which the first cut pattern and the second cut pattern are spaced apart from each other in the second direction is equal to a distance by which the second cut pattern and the third cut pattern are spaced apart from each other in the second direction.

15. The semiconductor device of claim 11, further comprising:
a first via pattern which connects the second lower wiring pattern and the first extension;
a second via pattern which connects the third lower wiring pattern and the second extension;
a third via pattern which connects the fourth lower wiring pattern and the second upper wiring pattern; and
a fourth via pattern which connects the fifth lower wiring pattern and the second upper wiring pattern.

16. The semiconductor device of claim 15, wherein the first via pattern, the third via pattern, and the fourth via pattern are arranged in a line along the second direction.

17. The semiconductor device of claim 15, wherein the first via pattern is not arranged along the second direction together with the third via pattern and the fourth via pattern.

18. A semiconductor device comprising:
a substrate;
a first active pattern which extends in a first direction on the substrate;
a second active pattern which is spaced apart from the first active pattern in a second direction intersecting the first direction, and extends in the first direction on the substrate;
a first gate structure which intersects the first active pattern;
a second gate structure which is spaced apart from the first gate structure in the first direction, and intersects the first active pattern;
a third gate structure which is spaced apart from the first gate structure in the second direction, and intersects the second active pattern;
a fourth gate structure which is spaced apart from the second gate structure in the second direction, and intersects the second active pattern;
a fifth gate structure which is spaced apart from the first gate structure and the third gate structure in the first direction, and intersects the first active pattern and the second active pattern;
first level wiring patterns which are disposed at a first level on the basis of an upper face of the substrate, and include first to fifth lower wiring patterns each extending in the first direction;
second level wiring patterns which are disposed at a second level higher than the first level on the basis of the upper face of the substrate, and include a first upper wiring pattern and a second upper wiring pattern; and
a connecting pattern which is connected to a first source/drain region of the first active pattern on a side face of the fifth gate structure, wherein:
the first to fourth lower wiring patterns are connected to the first to fourth gate structures, respectively,
the fifth lower wiring pattern is interposed between the second lower wiring pattern and the fourth lower wiring pattern,
the first upper wiring pattern includes a first extension extending in the first direction and connected to the second lower wiring pattern, and a second extension extending in the second direction from the first extension and connected to the third lower wiring pattern,
the second upper wiring pattern extends in the second direction and connects the fourth lower wiring pattern and the fifth lower wiring pattern, and
the connecting pattern extends in the second direction, and connects the first lower wiring pattern and the fifth lower wiring pattern.

19. The semiconductor device of claim 18, wherein the connecting pattern connects the first source/drain region and a second source/drain region of the second active pattern.

20. The semiconductor device of claim 18, wherein the second extension is disposed between the first gate structure and the fifth gate structure, and between the third gate structure and the fifth gate structure, from a planar point of view parallel to the upper face of the substrate.
